(19) United States
(12) Patent Application Publication
(10) Pub. No.: US 2025/0287765 A1
(43) Pub. Date: Sep. 11, 2025

(54) DISPLAY DEVICE

(71) Applicant: Japan Display Inc., Tokyo (JP)

(72) Inventors: Keisuke ASADA, Tokyo (JP); Kazuyuki YAMADA, Tokyo (JP); Kenichi TAKEMASA, Tokyo (JP); Daiki ISONO, Tokyo (JP)

(21) Appl. No.: 19/050,202

(22) Filed: Feb. 11, 2025

(30) Foreign Application Priority Data
Mar. 5, 2024 (JP) 2024-032912

(51) Int. Cl. H10H 29/85; H01L 25/075; H10H 29/14

(52) U.S. Cl. CPC H10H 29/857; H01L 25/0753; H10H 29/142

(57) ABSTRACT

The reliability of a display device improves. The present disclosure is to form a connection pad not from a simple metal film but from an insulating film that becomes conductive when pressure is applied.

### CROSS-REFERENCE TO RELATED APPLICATIONS

The present application claims priority to Japanese Patent Application No. 2024-32912 filed on Mar. 5, 2024, the disclosure of which is incorporated herein by reference.

### BACKGROUND

The present disclosure relates to a display device, and particularly to a technique that is effective when applied to a display device having a light-emitting diode, for example.

Japanese Patent No. 7146595 discloses a technique for forming a mounted electrode for repair in advance. In the technique, for example, when a light-emitting diode element disposed on a mounted electrode is defective, a light-emitting diode element is disposed on a mounted electrode for repair, and then the mounted electrode and the mounted electrode for repair are connected by a metallized line.

### SUMMARY

Among display devices, there is a Light Emitting Diode (LED) display device that uses, as a light source, a plurality of light-emitting diode elements disposed on a substrate called a backplane. In an LED display device, for example, some of the plurality of light-emitting diode elements may be non-mounted on the backplane. In this case, there is a risk of a short circuit defect occurring due to non-mounting of the light-emitting diode elements. Therefore, in an LED display device, even when non-mounting of a light-emitting diode element is present, innovations to improve the reliability of the LED display device are desired.

Other objects and novel features will become apparent from the description of the present specification and the accompanying drawings.

According to one embodiment, a display device includes a backplane having a first electrode and a plurality of second electrodes, a connection pad formed on each of the plurality of second electrodes, a light-emitting diode element disposed on the connection pad formed on a mounted electrode of the plurality of second electrodes, the light-emitting diode element having an upper electrode formed on a first surface and a lower electrode formed on a second surface located opposite to the first surface, an insulating film formed on the backplane so as to cover the light-emitting diode element, a first contact hole penetrating the insulating film and reaching the first electrode, a second contact hole penetrating the insulating film and reaching the connection pad formed on a non-mounted electrode of the plurality of second electrodes, a third contact hole penetrating the insulating film and reaching the upper electrode, and a transparent conductive film formed in the first contact hole, the second contact hole, the third contact hole and on the insulating film. The mounted electrode is a second electrode of the plurality of second electrodes on which the light-emitting diode element is disposed. The non-mounted electrode is a second electrode of the plurality of second electrodes on which the light-emitting diode element is non-mounted. The connection pad is formed from an insulating film that becomes conductive when pressure is applied. The connection pad formed on the mounted electrode has conductivity. The connection pad formed on the non-mounted electrode has insulation.

### BRIEF DESCRIPTION OF THE DRAWINGS

FIG. 1 is a plan view illustrating a configuration example of a display device.

FIG. 2 is a circuit diagram illustrating a configuration example of a circuit around a pixel.

FIG. 3 is a diagram illustrating a configuration of a pixel of “Type 1”.

FIG. 4 is a diagram illustrating a configuration of a pixel of “Type 2”.

FIG. 5 is a diagram illustrating a pixel in which a light-emitting diode element is non-mounted.

FIG. 6 is a diagram illustrating a manufacturing process of a display device, illustrating room for improvement.

FIG. 7 is a diagram illustrating a manufacturing process of the display device following FIG. 6.

FIG. 8 is a diagram illustrating a manufacturing process of the display device following FIG. 7.

FIG. 9 is a diagram illustrating a manufacturing process of the display device following FIG. 8.

FIG. 10 is a diagram illustrating a manufacturing process of the display device following FIG. 9.

FIG. 11 is a diagram illustrating a manufacturing process of the display device following FIG. 10.

FIG. 12 is a diagram illustrating a configuration of a display device in an implementation aspect.

FIG. 13 is a diagram illustrating a manufacturing process of the display device in an implementation aspect.

FIG. 14 is a diagram illustrating a manufacturing process of the display device following FIG. 13.

FIG. 15 is a diagram illustrating a manufacturing process of the display device following FIG. 14.

FIG. 16 is a diagram illustrating a manufacturing process of the display device following FIG. 15.

FIG. 17 is a diagram illustrating a manufacturing process of the display device following FIG. 16.

### DETAILED DESCRIPTION

Hereinafter, an embodiment will be described with reference to the drawings.

Note that the present disclosure is merely an example, and any modifications that those skilled in the art can easily conceive of while maintaining the gist of the present disclosure are naturally included within the scope of the present disclosure.

Additionally, the drawings may schematically represent the widths, thicknesses, shapes, and other aspects of each part compared to the actual embodiment to make the description clearer. However, they are merely examples and do not limit the interpretation of the present disclosure. In the present specification and each drawing, elements similar to those illustrated in the previous drawings are given the same reference numerals, and detailed descriptions thereof may be omitted as appropriate.

In the embodiment, a micro LED display device including a plurality of micro LED elements will be exemplified as an example of a display device using a plurality of light-emitting diode elements. The micro LED elements have a smaller element size (outer diameter dimensions) compared to the general LED elements. This allows the micro LED display device to display high-definition images.

### Configuration of Display Device

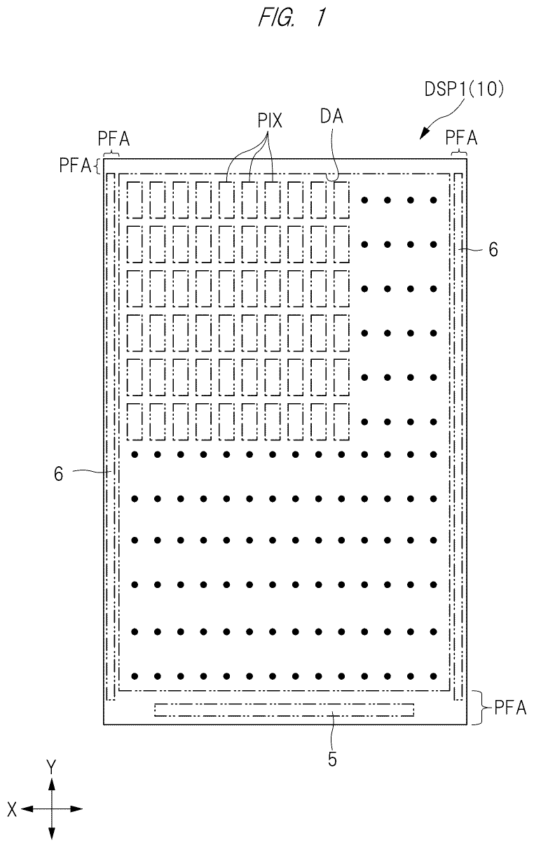

FIG. 1 is a plan view illustrating a configuration example of a display device.

In FIG. 1, the boundary between a display area DA and a peripheral area PFA, a control circuit 5, drive circuits 6, and a plurality of pixels PIX are each indicated by a two-dot chain line.

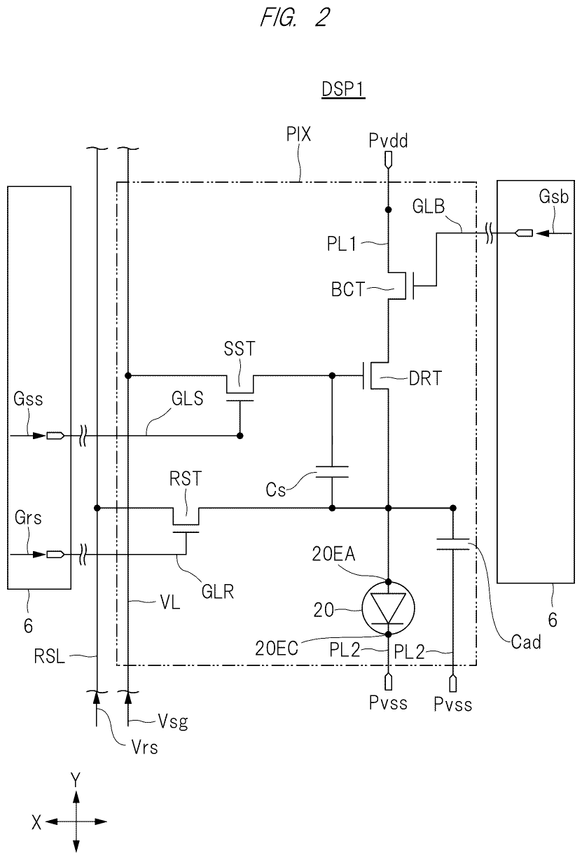

FIG. 2 is a circuit diagram illustrating a configuration example of a circuit around a pixel. The pixel circuit illustrated in FIG. 2 illustrates an example of an equivalent circuit corresponding to one pixel PIX illustrated in FIG. 1.

In FIG. 1, an X direction and a Y direction are illustrated. The X direction and the Y direction intersect with each other. In the example described below, the X direction is orthogonal to the Y direction. Also, the following description will be given assuming that the X-Y plane including the X direction and the Y direction is a plane parallel to a display surface of the display device.

Unless explicitly stated to be interpreted differently, the term “plan view” refers to the view of a plane parallel to the X-Y plane. Also, the normal direction to the X-Y plane will be described as the “Z direction” or thickness direction. The X direction, the Y direction and the Z direction intersect with each other. For example, the X direction, the Y direction and the Z direction are directions perpendicular to each other.

As illustrated in FIG. 1, a display device DSP1 includes the display area DA, the peripheral area PFA, and the plurality of pixels PIX. The peripheral area PFA surrounds the periphery of the display area DA in a frame shape. The plurality of pixels PIX is disposed in a matrix within the display area DA.

The display device DSP1 also includes a substrate 10, the control circuit 5, and the drive circuits 6. The control circuit 5 and the drive circuits 6 are each formed on the substrate 10.

The control circuit 5 is a circuit for controlling the display in the display device DSP1. For example, the control circuit 5 is a driver integrated circuit (IC) mounted on the substrate 10. In FIG. 1, the control circuit 5 is disposed, for example, along one of the short sides out of the four sides that define the outer shape of the substrate 10. The control circuit 5 includes a signal line drive circuit. The signal line drive circuit is a video driver. The signal line drive circuit is a circuit that supplies video signals to video signal lines. The position and a configuration example of the control circuit 5 are not limited to the example illustrated in FIG. 1. For example, in FIG. 1, a circuit board such as a flexible board may be connected to the position indicated as the control circuit 5. In this case, the control circuit 5 is mounted on the circuit board. For example, the signal line drive circuit may be formed separately from the control circuit 5.

The drive circuits 6 are scanning drivers. The drive circuits 6 are circuits that supply scanning signals to scanning signal lines. The drive circuits 6 supply scanning signals to the scanning signal lines based on control signals from the control circuit 5. The drive circuits 6 are disposed, for example, along each of two longer sides out of the four sides that define the outer shape of the substrate 10. In the example illustrated in FIG. 1, the display area DA is disposed between the two drive circuits 6 in plan view. The positions and a configuration example of the drive circuits 6 are not limited to the example illustrated in FIG. 1. For example, in FIG. 1, a circuit board such as a flexible board may be connected to the positions indicated as the drive circuits 6. In this case, the drive circuits 6 are mounted on the circuit board.

Next, a configuration example of a pixel circuit that drives a pixel PIX will be described with reference to FIG. 2.

In FIG. 2, one pixel circuit for driving one pixel is representatively illustrated. Each of the pixels PIX illustrated in FIG. 1 includes a circuit similar to the pixel circuit illustrated in FIG. 2. The pixel circuit is a voltage signal-based circuit that controls a light-emitting state of an LED element 20 based on a video signal Vsg supplied from the control circuit 5 (see FIG. 1).

As illustrated in FIG. 2, the pixel PIX includes an LED element 20. The LED element 20 is a light-emitting diode element. The LED element 20 has an anode electrode 20EA and a cathode electrode 20EC.

The display device DSP1 includes a plurality of types of lines in the display area DA. The lines include a plurality of scanning signal lines GLS, GLR, GLB, a plurality of video signal lines VL, a plurality of power supply lines PL1, a plurality of power supply lines PL2, and a plurality of reset lines RSL.

The scanning signal lines GLS, GLR, GLB extend in the X direction. The scanning signal lines GLS, GLR, GLB are connected to the drive circuits 6. For example, as illustrated in FIG. 1, among the pixels PIX aligned in the Y direction, the scanning signal lines GLS, GLR, GLB for driving the even-numbered pixels PIX are connected to one of the drive circuits 6. Whereas, for example, the scanning signal lines GLS, GLR, GLB for driving the odd-numbered pixels PIX are connected to the other drive circuit 6. As another example, a configuration may also be considered in which the scanning signal lines GLS, GLR are all connected to one drive circuit 6, and the scanning signal lines GLB are all connected to the other drive circuit 6. Accordingly, any of the scanning signal lines GLS, GLR, GLB may be connected to the one drive circuit 6, and the rest may be connected to the other drive circuit 6.

The video signal lines VL, the power supply lines PL1, PL2, and the reset lines RSL extend in the Y direction. The video signal lines VL are connected to the control circuit 5 (see FIG. 1). A video signal line VL is supplied with a video signal Vsg and an initialization signal from the control circuit 5. A power supply line PL1 is supplied with a high potential Pvdd from the control circuit 5. A power supply line PL2 is supplied with a low potential Puss lower than the high potential Pvdd from the control circuit 5. A reset line RSL is supplied with a reset signal Vrs from the control circuit 5.

The control circuit 5 outputs a start pulse signal and a clock signal (not illustrated) to the drive circuits 6. The drive circuits 6 include a plurality of shift register circuits. The drive circuits 6 sequentially transfer a start pulse signal to the next-stage shift register circuit based on a clock signal. Accordingly, the drive circuits 6 sequentially supply the scanning signals to the scanning signal lines GLS, GLR, GLB.

The pixel circuit controls the LED element 20 based on the video signal Vsg supplied to the video signal line VL. To implement such control, the pixel circuit includes a reset transistor RST, a pixel selection transistor SST, an output transistor BCT, a drive transistor DRT, a storage capacitor Cs, and an auxiliary capacitor Cad. The auxiliary capacitor Cad is an element provided to adjust the amount of light emission current.

The reset transistor RST, the pixel selection transistor SST, the output transistor BCT, and drive transistor DRT are switching elements formed from thin-film transistors (TFTs). The conductivity type of the thin-film transistors is not particularly limited. For example, all the transistors may be composed of N-channel type TFTs. However, at least one of the transistors may be composed of a P-channel type TFT.

The reset transistor RST, the pixel selection transistor SST, the output transistor BCT, and the drive transistor DRT are formed, for example, in the same process and with the same layer structure. These transistors have a bottom gate structure using polycrystalline silicon for a semiconductor layer. As another example, the reset transistor RST, the pixel selection transistor SST, the output transistor BCT, and the drive transistor DRT may have a top-gate structure. The semiconductor layer may be made of, for example, an oxide semiconductor or a polycrystalline GaN semiconductor.

The reset transistor RST, the pixel selection transistor SST, the output transistor BCT, and the drive transistor DRT each have a source electrode, a drain electrode, and a gate electrode.

The gate electrode of each transistor is a control electrode. Also, the source electrode and the drain electrode of each transistor can be simply referred to as electrodes.

The drive transistor DRT and the output transistor BCT are connected in series with the LED element 20 between the power supply line PL1 and the power supply line PL2. The high potential Pvdd supplied to the power line PL1 is set to, for example, 10V. The low potential Pvss supplied to the power line PL2 is set to, for example, 1.5V.

The drain electrode of the output transistor BCT is connected to the power supply line PL1. The source electrode of the output transistor BCT is connected to the drain electrode of the drive transistor DRT. The gate electrode of the output transistor BCT is connected to the scanning signal line GLB. The output transistor BCT is turned ON/OFF by a control signal Gsb supplied to the scanning signal line GLB. Here, ON represents a conductive state and OFF represents a non-conductive state. The output transistor BCT controls the light emission time of the LED element 20 based on the control signal Gsb.

The source electrode of the drive transistor DRT is connected to one electrode of the LED element 20 (here, the anode electrode 20EA). The other electrode of the LED element 20 (here, the cathode electrode 20EC) is connected to the power supply line PL2. The drive transistor DRT outputs a drive current based on the video signal Vsg to the LED element 20.

The source electrode of the pixel selection transistor SST is connected to the video signal line VL. The drain electrode of the pixel selection transistor SST is connected to the gate electrode of the drive transistor DRT. The gate electrode of the pixel selection transistor SST is connected to the scanning signal line GLS. The scanning signal line GLS functions as a gate line for signal write control. The pixel selection transistor SST is turned ON/OFF by a control signal Gss supplied from the scanning signal line GLS. By turning ON/OFF the pixel selection transistor SST, the pixel circuit and the video signal line VL are switched between connection and disconnection. That is, by turning ON the pixel selection transistor SST, the video signal Vsg or the initialization signal of the video signal line VL is supplied to the gate electrode of the drive transistor DRT.

The source electrode of the reset transistor RST is connected to the reset line RSL. The drain electrode of the reset transistor RST is connected to the source electrode of the drive transistor DRT and the anode electrode 20EA of the LED element 20. The gate electrode of the reset transistor RST is connected to the scanning signal line GLR. The scanning signal line GLR functions as a gate line for reset control. The reset transistor RST is turned ON/OFF by a control signal Grs supplied from the scanning signal line GLR. By switching ON the reset transistor RST, the potentials of the source electrode of the drive transistor DRT and the anode electrode 20EA of the LED element 20 can be reset. That is, the potentials of the source electrode of the drive transistor DRT and the anode electrode 20EA of the LED element 20 can be reset to the reset signal Vrs supplied to the reset line RSL. In other words, the reset line RSL is a line for resetting the voltage of the LED element 20.

The storage capacitor Cs is connected between the gate electrode and the source electrode of the drive transistor DRT. The auxiliary capacitor Cad is connected between the source electrode of the drive transistor DRT and the power line PL2.

The drive circuits 6 sequentially supply the scanning signals (control signals Gss, Grs, Gsb) to the respective scanning signal lines GLS, GLR, GLB. That is, the control signals Gss, Grs, Gsb are sequentially supplied to the scanning signal lines GLS, GLR, GLB of each line (a series of pixels PIX aligned in the X direction) based on a start pulse signal and a clock signal. Moreover, the control circuit 5 sequentially supplies the video signal Vsg and the initialization signal to each video signal line VL. The charge held in the storage capacitor Cs in response to the supply of the video signal Vsg is initialized in response to the supply of the initialization signal.

In the above configuration, the pixel circuit is driven by the control signals Gss, Grs, Gsb supplied to the scanning signal lines GLS, GLR, GLB. Meanwhile, the LED element 20 emits light with a luminance according to the video signal Vsg supplied to the video signal line VL.

### Pixel Configuration

Next, a pixel configuration will be described. The pixel configuration includes, for example, a configuration called “Type 1” and a configuration called “Type 2”. “Type 1” is a configuration based on a non-redundant design. On the other hand, “Type 2” is a configuration based on a redundant design.

### 1. Configuration of “Type 1”

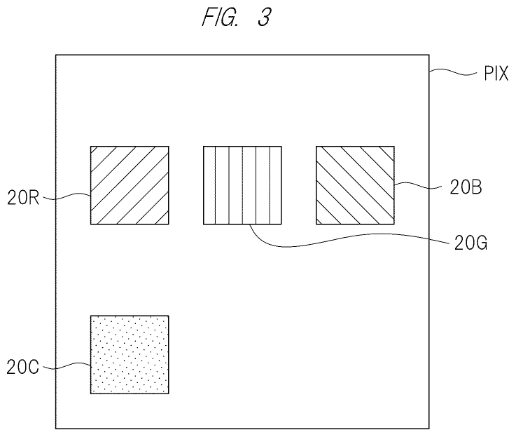

FIG. 3 is a diagram illustrating the configuration of a pixel of “Type 1”.

The pixel PIX includes a plurality of light-emitting diode elements. Specifically, the pixel PIX includes one red light-emitting diode element 20R, one green light-emitting diode element 20G, one blue light-emitting diode element 20B, and one electrode 20C. As illustrated in FIG. 2, the electrode 20C is an electrode corresponding to the power line PL2 to which the low potential Pvss is supplied.

The pixel PIX of “Type 1” thus configured becomes a defective pixel when, for example, non-mounting of one light-emitting diode element is present. For this reason, the pixel PIX of “Type 1” is configured based on the non-redundant design.

### 2. Configuration of “Type 2”

FIG. 4 is a diagram illustrating the configuration of a pixel of “Type 2”.

The pixel PIX includes a plurality of light-emitting diode elements. Specifically, the pixel PIX includes two or more red light-emitting diode elements 20R, two or more green light-emitting diode elements 20G, two or more blue light-emitting diode elements 20B, and one electrode 20C. As illustrated in FIG. 2, the electrode 20C is an electrode corresponding to the power line PL2 to which the low potential Pvss is supplied.

The pixel PIX of “Type 2” thus configured does not become a defective pixel even when, for example, non-mounting of one light-emitting diode element is present. For example, when the non-mounted light-emitting diode element is one red light-emitting diode element 20R, the pixel PIX of “Type 2” includes another red light-emitting diode element 20R. For this reason, the pixel PIX of “Type 2” does not become a defective pixel even when one red light-emitting diode element 20R is non-mounted. For this reason, the pixel PIX of “Type 2” is configured based on the redundant design. That is, in a display device including the pixels PIX of “Type 2”, even if a non-mounted pixel is present, it will still function as a normal display device.

From the above, it is considered that a normal display device can be implemented even if non-mounting of a light-emitting diode element is present. However, there is a concern about a risk of a short circuit defect occurring due to non-mounting of the light-emitting diode element.

### Room for Improvement

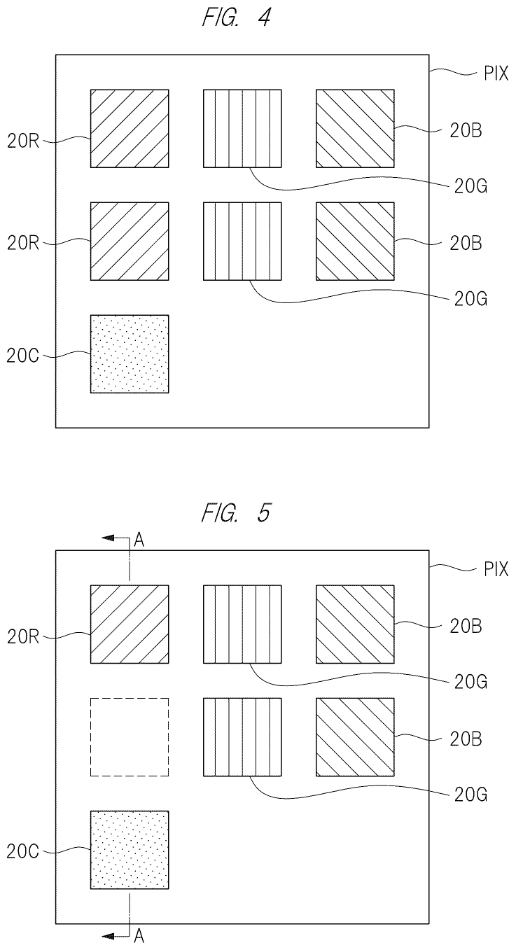

FIG. 5 is a diagram illustrating a pixel PIX in which a light-emitting diode element is non-mounted.

In FIG. 5, a pixel PIX of “Type 2” is illustrated. A position indicated by the dashed line is where non-mounting of a light-emitting diode element is present. In the following, referring to a cross-sectional view taken along line A-A in FIG. 5, a description will be given of the room for improvement that becomes apparent in the pixel PIX, where a light-emitting diode is non-mounted.

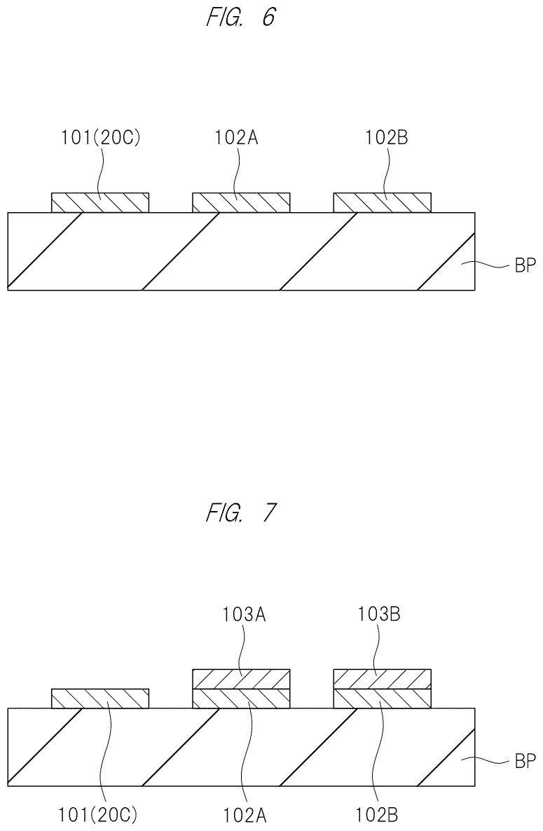

As illustrated in FIG. 6, a backplane BP is prepared. An electrode 101, an electrode 102A, and an electrode 102B are formed on the upper surface of the backplane BP. That is, the backplane BP has the electrode 101 and a plurality of electrodes (electrode 102A, electrode 102B).

Next, a metal film is formed on the backplane BP. The metal film is made of, for example, tin (Sn), indium (In) or solder. Then, the metal film is patterned by using photolithography technique and etching technique. Accordingly, as illustrated in FIG. 7, a connection pad 103A is formed on the electrode 102A, and a connection pad 103B is formed on the electrode 102B. That is, the metal film is patterned so as to form the connection pad 103A on the electrode 102A and the connection pad 103B on the electrode 102B.

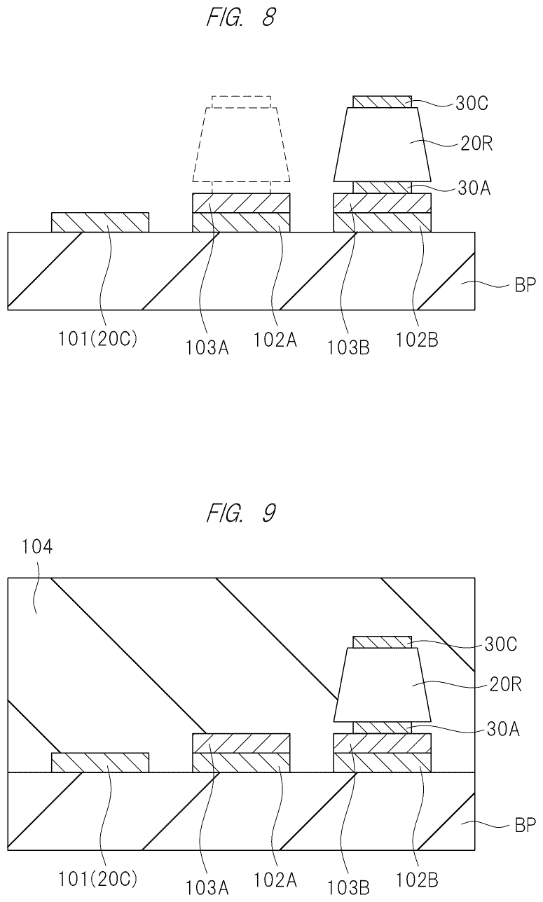

Subsequently, as illustrated in FIG. 8, the red light-emitting diode element 20R is disposed on the connection pad 103B. The red light-emitting diode element 20R has an anode electrode 30A and a cathode electrode 30C. The red light-emitting diode element 20R is configured to emit red light by passing a current between the anode electrode 30A and the cathode electrode 30C.

In FIG. 8, a red light-emitting diode element 20R is also to be disposed on the connection pad 103A in the design. However, in practice, due to some malfunction, the red light-emitting diode element 20R is not disposed on the connection pad 103A. In other words, non-mounting of the red light-emitting diode element 20R has occurred on the connection pad 103A.

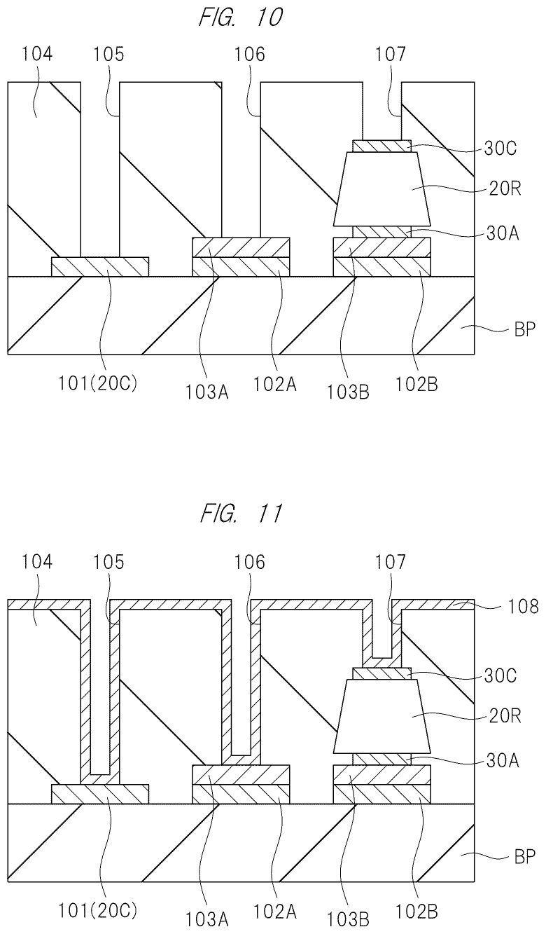

On the premise of this configuration, as illustrated in FIG. 9, an insulating film 104 is formed on the backplane BP so as to cover the red light-emitting diode element 20R. Thereafter, as illustrated in FIG. 10, a contact hole 105, a contact hole 106, and a contact hole 107 are formed in the insulating film 104 by using photolithography technique and etching technique. The contact hole 105 is formed so as to reach the electrode 101. The contact hole 106 is formed so as to reach the connection pad 103A. The contact hole 107 is formed so as to reach the cathode electrode 30C of the red light-emitting diode element 20R.

Here, attention is focused on the contact hole 106. On the connection pad 103A is where the red light-emitting diode element 20R was supposed to be disposed. If the red light-emitting diode element 20R is properly mounted on the connection pad 103A, the contact hole 106 would be formed so as to reach the cathode electrode of the red light-emitting diode element 20R, similar to the contact hole 107. As a result, the contact hole 106 does not reach the connection pad 103A. However, in practice, non-mounting of the red light-emitting diode element 20R has occurred on the connection pad 103A. Therefore, the contact hole 106 is formed to extend to the connection pad 103A.

Next, as illustrated in FIG. 11, a transparent conductive film 108 is formed in the contact hole 105, the contact hole 106, and the contact hole 107 and on the insulating film 104. The transparent conductive film 108 is, for example, an Indium Tin Oxide (ITO) film.

Due to this, the electrode 101 is electrically connected to the transparent conductive film 108 at the bottom of the contact hole 105. Also, the connection pad 103A is electrically connected to the transparent conductive film 108 at the bottom of the contact hole 106. As a result, the electrode 102A is electrically connected to the transparent conductive film 108 via the connection pad 103A. Furthermore, the cathode electrode 30C of the red light-emitting diode element 20R is electrically connected to the transparent conductive film 108 at the bottom of the contact hole 107.

Here, when the red light-emitting diode element 20R is disposed on the connection pad 103A, the electrode 102A is connected to the anode electrode via the connection pad 103A. In other words, the electrode 102A is originally an electrode that is connected to the anode electrode. However, as illustrated in FIG. 11, if the red light-emitting diode element 20R is not disposed on the connection pad 103A, the electrode 102A will be electrically connected to the cathode electrode 30C via the connection pad 103A and the transparent conductive film 108. Similarly, the electrode 102A ends up electrically connected to the electrode 101. That is, the electrode 102A, which is supposed to be electrically connected to the anode electrode, is electrically connected to the cathode electrode 30C and the power supply line PL2 (see FIG. 2) to which the low potential Pvss is supplied. This means that a short circuit defect occurs.

Accordingly, when non-mounting of a light-emitting diode element is present, a short circuit defect may occur due to the non-mounting of the light-emitting diode element. In other words, when non-mounting of a light-emitting diode element is present, there is room for improvement in that a short circuit defect occurs.

Therefore, in the embodiment, innovations are made to overcome the above-mentioned room for improvement. The technical concept of the embodiment that incorporates innovations will be described below.

### Basic Concept of Embodiment

The basic concept of the embodiment is to form the connection pad not from a simple metal film but from an insulating film that becomes conductive when pressure is applied.

In the present specification, when a light-emitting diode element is disposed on an electrode via a connection pad, the electrode is referred to as a “mounted electrode”.

Whereas, when a light-emitting diode element is not disposed on an electrode via a connection pad, the electrode is referred to as a “non-mounted electrode”.

The basic concept is that pressure is applied to the connection pad formed on the mounted electrode due to the load applied when the light-emitting diode element is disposed on the connection pad. As a result, the connection pad formed on the mounted electrode has conductivity. On the other hand, no light-emitting diode element is disposed on the connection pad formed on the non-mounted electrode. Therefore, no load is applied to the connection pad formed on the non-mounted electrode when the light-emitting diode element is disposed. Therefore, the insulating film forming the connection pad formed on the non-mounted electrode does not become conductive. In other words, the connection pad formed on the non-mounted electrode has insulation.

As a result, according to the basic concept, the mounted electrode is electrically connected, via the connection pad, to the anode electrode (lower electrode) of the light-emitting diode element disposed on the connection pad. In contrast, the non-mounted electrode is electrically insulated from the transparent electrode formed in a contact hole that reaches the connection pad. The transparent electrode is electrically connected to the cathode electrode of the light-emitting diode element. Therefore, the non-mounted electrode is electrically insulated from the cathode electrode (upper electrode). Accordingly, according to the basic concept, by forming a connection pad from an insulating film that becomes conductive when pressure is applied, it is possible to achieve electrical insulation between the non-mounted electrode and the cathode electrode while securing electrical connection between the mounted electrode and the anode electrode. As a result, according to the basic concept, even if non-mounting of a light-emitting diode element is present, it is possible to prevent a short circuit defect between the non-mounted electrode that is originally connected to the anode electrode and the cathode electrode.

The following describes an implementation aspect that implements the basic concept.

### Implementation Aspect

### Configuration of Display Device

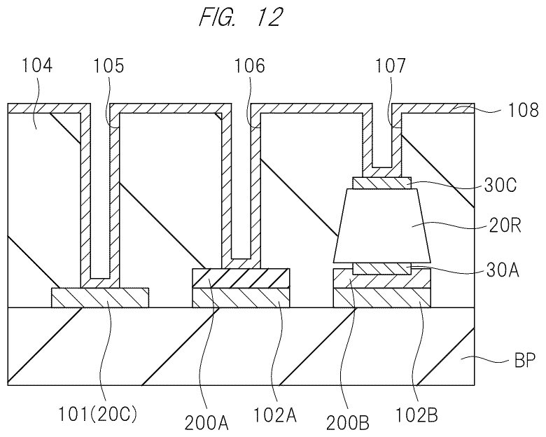

FIG. 12 is a diagram illustrating a configuration of a display device in an implementation aspect.

In FIG. 12, the display device includes a backplane BP, an electrode 101, an electrode 102A, an electrode 102B, a connection pad 200A, a connection pad 200B, a red light-emitting diode element 20R, an insulating film 104, a contact hole 105, a contact hole 106, a contact hole 107 and a transparent conductive film 108.

The backplane BP has the electrode 101 and a plurality of electrodes (electrode 102A, electrode 102B). The electrode 102A is a non-mounted electrode. On the other hand, the electrode 102B is a mounted electrode. The backplane BP has transparency.

The connection pad 200A is formed on the electrode 102A. Also, the connection pad 200B is formed on the electrode 102B. Each of the connection pad 200A and the connection pad 200B is formed from a patterned anisotropic conductive film or a patterned non-conductive film.

The red light-emitting diode element 20R is disposed on the connection pad 200B. The red light-emitting diode element 20R has an upper electrode formed on an upper surface (first surface) and a lower electrode formed on a lower surface (second surface) located opposite to the upper surface. For example, in the implementation aspect, the upper electrode is the cathode electrode 30C. On the other hand, the lower electrode is the anode electrode 30A. The anode electrode 30A is connected to the connection pad 200B.

The insulating film 104 is formed on the backplane BP. The insulating film 104 is formed on the backplane BP so as to cover the red light-emitting diode element 20R. In the insulating film 104, the contact hole 105, the contact hole 106, and the contact hole 107 are formed. The contact hole 105 is formed so as to penetrate the insulating film 104 and reach the electrode 101. The contact hole 106 is formed so as to penetrate the insulating film 104 and reach the connection pad 200A formed on the electrode 102A (non-mounted electrode). The contact hole 107 is formed so as to penetrate the insulating film 104 and reach the cathode electrode 30C of the red light-emitting diode element 20R.

The transparent conductive film 108 is formed in the contact hole 105, the contact hole 106, and the contact hole 107 and on the insulating film 104. The transparent conductive film 108 is, for example, an ITO film. Due to this, the transparent conductive film 108 is connected to the electrode 101 at the bottom of the contact hole 105. Also, the transparent conductive film 108 is connected to the connection pad 200A at the bottom of the contact hole 106. Further, the transparent conductive film 108 is connected to the cathode electrode 30C at the bottom of the contact hole 107.

The display device in the implementation aspect is configured as described above.

### Features of Implementation Aspect

Features of the implementation aspect is that the connection pad is formed from a patterned anisotropic conductive film or a patterned non-conductive film.

An “anisotropic conductive film” is a film in which conductive particles are dispersed in a resin. When the anisotropic conductive film is thermocompression-bonded, the bonded portion thereof has conductivity in the bonding direction (vertical direction). On the other hand, it has insulation in a direction perpendicular to the bonding direction (plane direction). That is, an anisotropic conductive film exhibits “electrical anisotropy”. In an anisotropic conductive film, conductive particles are compressed and come into contact between the electrodes in the bonding direction, resulting in the formation of a conductive path. On the other hand, the conductive particles that are not compressed remain dispersed in the resin, and therefore maintain insulation from adjacent electrodes in the planar direction. Therefore, when the connection pad 200B illustrated in FIG. 12 is formed from an anisotropic conductive film, pressure is applied to the connection pad 200B when disposing the red light-emitting diode element 20R on the connection pad 200B, and as a result, the anisotropic conductive film forming the connection pad 200B has conductivity. Therefore, the electrode 102B (mounted electrode) is electrically connected to the anode electrode 30A via the connection pad 200B.

On the other hand, the red light-emitting diode is non-mounted on the connection pad 200A illustrated in FIG. 12. Therefore, no pressure is applied to the connection pad 200A. Therefore, the anisotropic conductive film forming the connection pad 200A maintains its insulation. As a result, the connection pad 200A having insulation is interposed between the electrode 102A (non-mounted electrode) and the transparent conductive film 108. Accordingly, the electrode 102A is electrically insulated from the transparent conductive film 108.

In this manner, electrical insulation between the electrode 102A and the transparent conductive film 108 can be achieved while securing electrical connection between the electrode 102B and the anode electrode 30A. As a result, according to the implementation aspect, even if non-amounting of a light-emitting diode element is present, the electrode 102A that is originally connected to the anode electrode is electrically insulated from the transparent conductive film 108 that is electrically connected to the cathode electrode 30C. Consequently, according to the implementation aspect, a short circuit defect between the electrode 102A and the transparent conductive film 108 can be prevented.

A non-conductive film may also be used. In this case as well, the connection pad 200A having insulation is interposed between the electrode 102A and the transparent conductive film 108. Accordingly, the electrode 102A is electrically insulated from the transparent conductive film 108. In contrast, the anode electrode 30A of the red light-emitting diode element 20R disposed on the connection pad 200B penetrates through the non-conductive film forming the connection pad 200B due to the load applied. As a result, the anode electrode 30A is electrically connected to the electrode 102B.

In this manner, even when a non-conductive film is used, electrical insulation between the electrode 102A and the transparent conductive film 108 can be achieved while securing electrical connection between the electrode 102B and the anode electrode 30A. As a result, according to the implementation aspect, even if non-amounting of a light-emitting diode element is present, the electrode 102A that is originally connected to the anode electrode is electrically insulated from the transparent conductive film 108 that is electrically connected to the cathode electrode 30C. Consequently, according to the implementation aspect, a short circuit defect between the electrode 102A and the transparent conductive film 108 can be prevented.

### Manufacturing Method of Display Device

Next, a method of manufacturing the display device in the implementation aspect will be described.

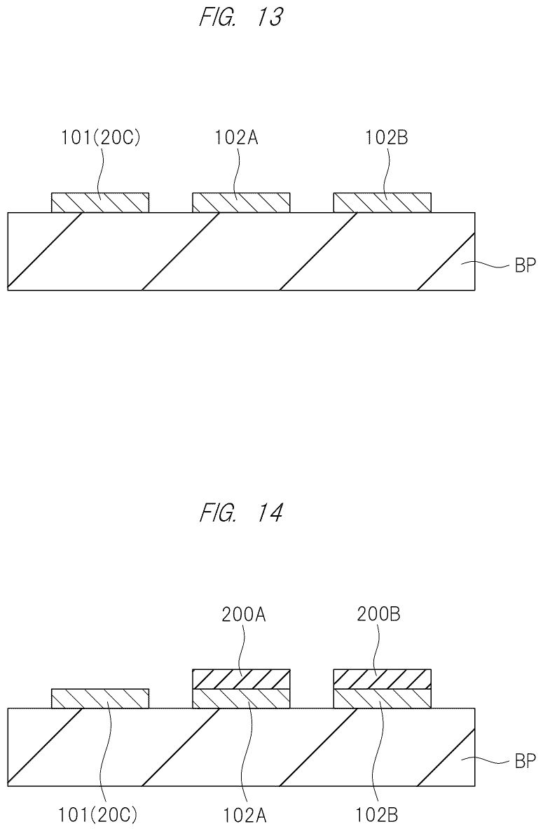

As illustrated in FIG. 13, a backplane BP is prepared. An electrode 101, an electrode 102A, and an electrode 102B are formed on the upper surface of the backplane BP. That is, the backplane BP has the electrode 101 and a plurality of electrodes (electrode 102A, electrode 102B).

Next, an anisotropic conductive film is disposed on the backplane BP on which the electrode 101, the electrode 102A, and the electrode 102B are formed. Then, the anisotropic conductive film is patterned by using photolithography technique and etching technique. Accordingly, as illustrated in FIG. 14, a connection pad 200A is formed on the electrode 102A, and a connection pad 200B is formed on the electrode 102B. Each of the connection pad 200A and the connection pad 200B is formed from the patterned anisotropic conductive film. At this stage, no pressure is applied to the anisotropic conductive film. Therefore, the anisotropic conductive film has insulation. That is, each of the connection pad 200A and the connection pad 200B is formed from the anisotropic conductive film having insulation.

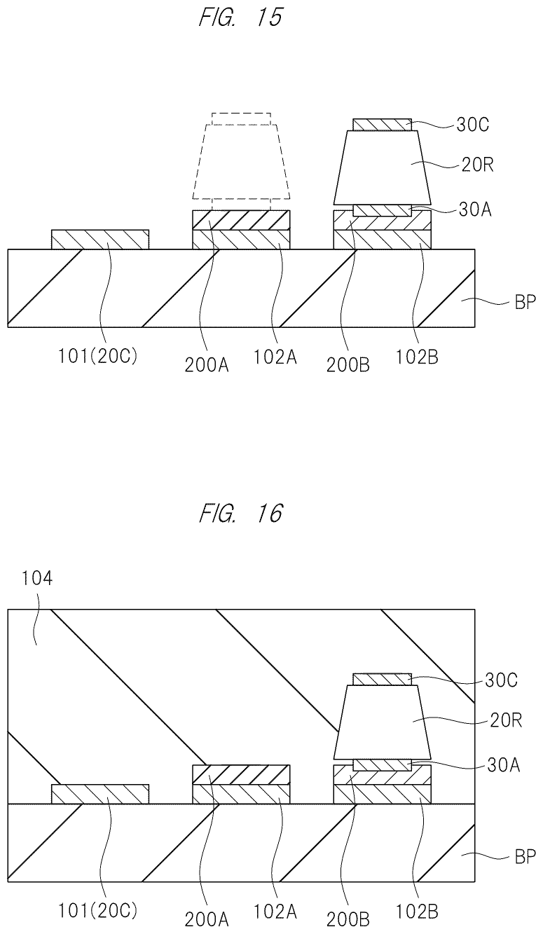

Then, as illustrated in FIG. 15, a red light-emitting diode element 20R is disposed on the connection pad 200B. The red light-emitting diode element 20R has an anode electrode 30A and a cathode electrode 30C. The red light-emitting diode element 20R is configured to emit red light by passing a current between the anode electrode 30A and the cathode electrode 30C.

Here, when the connection pad 200B is formed from an anisotropic conductive film, pressure is applied to the connection pad 200B when disposing the red light-emitting diode element 20R on the connection pad 200B. As a result, conductive particles contained in the anisotropic conductive film are compressed to form a conductive path. Therefore, the anisotropic conductive film forming the connection pad 200B has conductivity. Therefore, the electrode 102B is electrically connected to the anode electrode 30A via the connection pad 200B.

It should be noted that, in FIG. 15, a red light-emitting diode element 20R is also to be disposed on the connection pad 200A in design. However, in practice, due to some malfunction, the red light-emitting diode element 20R is not disposed on the connection pad 200A. In other words, non-mounting of the red light-emitting diode element 20R has occurred on the connection pad 200A. As a result, no pressure is applied to the anisotropic conductive film forming the connection pad 200A. As a result, conductive particles contained in the anisotropic conductive film are not compressed. Therefore, the anisotropic conductive film forming the connection pad 200A does not have conductivity. In other words, the anisotropic conductive film forming the connection pad 200A maintains its insulation.

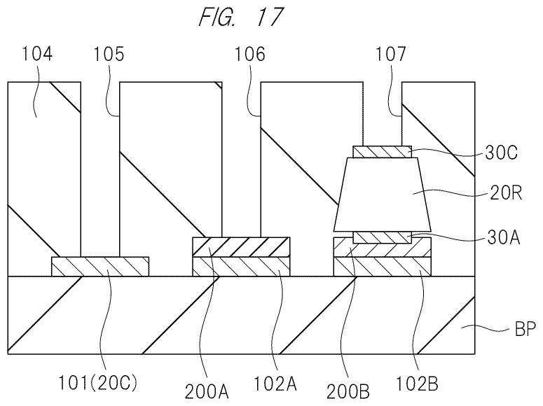

Subsequently, as illustrated in FIG. 16, an insulating film 104 is formed on the backplane BP so as to cover the red light-emitting diode element 20R. Thereafter, as illustrated in FIG. 17, a contact hole 105, a contact hole 106, and a contact hole 107 are formed in the insulating film 104 by using photolithography technique and etching technique. The contact hole 105 is formed so as to reach the electrode 101. The contact hole 106 is formed so as to reach the connection pad 200A. The contact hole 107 is formed so as to reach the cathode electrode 30C of the red light-emitting diode element 20R.

Here, attention is focused on the contact hole 106. The red light-emitting diode element 20R was supposed to be disposed on the connection pad 200A. The contact hole 106 is formed so as to reach the cathode electrode of the red light-emitting diode element 20R. As a result, the contact hole 106 does not reach the connection pad 200A. However, in practice, non-mounting of the red light-emitting diode element 20R has occurred on the connection pad 200A. Therefore, the contact hole 106 is formed to extend to the connection pad 200A.

Next, as illustrated in FIG. 12, a transparent conductive film 108 is formed in the contact hole 105, the contact hole 106, and the contact hole 107 and on the insulating film 104. The transparent conductive film 108 is, for example, an Indium Tin Oxide (ITO) film.

Due to this, the electrode 101 is electrically connected to the transparent conductive film 108 at the bottom of the contact hole 105. On the other hand, the connection pad 200A maintains its insulation. Accordingly, the electrode 102A is electrically insulated from the transparent conductive film 108 at the bottom of the contact hole 106. Also, the cathode electrode 30C of the red light-emitting diode element 20R is electrically connected to the transparent conductive film 108 at the bottom of the contact hole 107.

The display device in the implementation aspect is manufactured as described above.

According to the implementation aspect, each of the connection pad 200A and the connection pad 200B is formed from the patterned anisotropic conductive film. In this manner, electrical insulation between the electrode 102A and the transparent conductive film 108 can be achieved while securing electrical connection between the electrode 102B and the anode electrode 30A. As a result, according to the implementation aspect, even if non-amounting of a light-emitting diode element is present, the electrode 102A that is originally connected to the anode electrode is electrically insulated from the transparent conductive film 108 that is electrically connected to the cathode electrode 30C. Consequently, a short circuit defect between the electrode 102A and the transparent conductive film 108 can be prevented.

### Modification

In the embodiment, although an example in which the connection pad is formed from an anisotropic conductive film or a non-conductive film has been described, the technical concept of the embodiment is not limited thereto. For example, the connection pad may be formed from a metal film with an oxidized surface.

In this case, pressure is applied to the connection pad 200B when the red light-emitting diode element 20R is disposed. Therefore, the anode electrode 30A penetrates through the oxide film formed on the surface of the connection pad 200B by the pressure and is electrically connected to the metal film forming the connection pad 200B. On the other hand, no pressure is applied to the non-mounted connection pad 200A. Therefore, the oxide film is present on the surface of the connection pad 200A. Therefore, insulation of the connection pad 200A is maintained. From the above, even if the connection pad is formed from a metal film with an oxidized surface, electrical insulation between the electrode 102A and the transparent conductive film 108 can be achieved while securing electrical connection between the electrode 102B and the anode electrode 30A.

In the foregoing, the present disclosure made by the inventors of the present application has been concretely described on the basis of the embodiments. However, it is needless to say that the present disclosure is not limited to the foregoing embodiments, and various modifications and alterations can be made within scope of the present disclosure.

Within the scope of the concept of the present disclosure, a person skilled in the art may conceive of various modifications and alterations, and it will be understood that these modifications and alterations also fall within the scope of the present disclosure. For example, modifications to the above-described embodiment, such as the addition, deletion, or design changes of components, or the addition, omission, or condition changes of processes, as deemed appropriate by those skilled in the art, are also included within the scope of the present disclosure, provided they embody the gist of the present disclosure.

Furthermore, any other effects and advantages evident from the description of the present specification or those that can be appropriately conceived by those skilled in the art, beyond those described in the embodiment, are naturally understood to be provided by the present disclosure.

What is claimed is:

1. A display device comprising:
a backplane having a first electrode and a plurality of second electrodes;
a connection pad formed on each of the plurality of second electrodes;
a light-emitting diode element disposed on the connection pad formed on a mounted electrode of the plurality of second electrodes, the light-emitting diode element having an upper electrode formed on a first surface and a lower electrode formed on a second surface located opposite to the first surface;
an insulating film formed on the backplane so as to cover the light-emitting diode element;
a first contact hole penetrating the insulating film and reaching the first electrode;
a second contact hole penetrating the insulating film and reaching the connection pad formed on a non-mounted electrode of the plurality of second electrodes;
a third contact hole penetrating the insulating film and reaching the upper electrode; and
a transparent conductive film formed in the first contact hole, the second contact hole, the third contact hole and on the insulating film,
wherein the mounted electrode is a second electrode of the plurality of second electrodes on which the light-emitting diode element is disposed,
wherein the non-mounted electrode is a second electrode of the plurality of second electrodes on which the light-emitting diode element is non-mounted,
wherein the connection pad is formed from an insulating film that becomes conductive when pressure is applied,
wherein the connection pad formed on the mounted electrode has conductivity, and
wherein the connection pad formed on the non-mounted electrode has insulation.

2. The display device according to claim 1,
wherein the mounted electrode is electrically connected to the lower electrode,
wherein the non-mounted electrode is electrically insulated from the transparent conductive film, and
wherein the first electrode is electrically connected to the transparent conductive film.

3. The display device according to claim 1,
wherein the connection pad is formed from a patterned anisotropic conductive film or a patterned non-conductive film.

4. The display device according to claim 1,
wherein the connection pad is formed from a metal film with an oxidized surface.

5. The display device according to claim 1,
wherein the upper electrode is a cathode electrode, and
wherein the lower electrode is an anode electrode.

6. The display device according to claim 1,
wherein the transparent conductive film is an ITO film.

7. The display device according to claim 1,
wherein the display device includes a plurality of pixels,
wherein each of the plurality of pixels includes a plurality of the light-emitting diode elements, and
wherein the plurality of light-emitting diode elements includes one red light-emitting diode element, one green light-emitting diode element, and one blue light-emitting diode element.

8. The display device according to claim 1,
wherein the display device includes a plurality of pixels,
wherein each of the plurality of pixels includes a plurality of the light-emitting diode elements, and
wherein the plurality of light-emitting diode elements includes two or more red light-emitting diode elements, two or more green light-emitting diode elements, and two or more blue light-emitting diode elements.
